(19) United States
(12) Patent Application Publication
(10) Pub. No.: US 2024/0431032 A1
(43) Pub. Date: Dec. 26, 2024

(54) LATERALLY PLACED CAPACITOR PACKAGE ASSEMBLY AND ASSEMBLY METHOD THEREOF

(71) Applicant: APAQ TECHNOLOGY CO., LTD., Miaoli County (TW)

(72) Inventors: CHING-FENG LIN, HSINCHU COUNTY (TW); CHIEH LIN, HSINCHU COUNTY (TW); MING-TSUNG LIANG, NEW TAIPEI CITY (TW); CHUNG-JUI SU, KAOHSIUNG CITY (TW)

(21) Appl. No.: 18/417,051

(22) Filed: Jan. 19, 2024

(30) Foreign Application Priority Data
Jun. 20, 2023 (TW) 112123078

(51) Int. Cl. H05K 1/18; H05K 3/30

(52) U.S. Cl. CPC H05K 1/182; H05K 3/301; H05K 2201/09072; H05K 2201/10015; H05K 2201/10583; H05K 2201/10606; H05K 2201/10651; H05K 2201/10795

(57) ABSTRACT

A laterally placed capacitor package assembly and an assembly method thereof are provided. The laterally placed capacitor package assembly includes a wound capacitor package structure and a capacitor supporting structure. The wound capacitor package structure includes a wound assembly, a conductive assembly and a package assembly. The conductive assembly includes a first conductive pin and a second conductive pin. The capacitor supporting structure includes a supporting portion configured to support the wound capacitor package structure and a plurality of positioning portions extending outward from the supporting portion. When the laterally placed capacitor package assembly is configured to be laterally disposed on a circuit substrate, a first exposed portion of the first conductive pin and a second exposed portion of the second conductive pin can be laterally and electrically connected to the circuit substrate without bending.

### CROSS-REFERENCE TO RELATED PATENT APPLICATION

This application claims the benefit of priority to Taiwan Patent Application No. 112123078, filed on Jun. 20, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a capacitor package assembly and an assembly method thereof, and more particularly to a laterally placed capacitor package assembly and an assembly method thereof.

### BACKGROUND OF THE DISCLOSURE

Applications of capacitors include being widely used in home appliances, computer motherboards and peripherals, power supplies, communication products and automobiles. The capacitors are mainly used to provide functions such as filtering, bypassing, rectifying, coupling, blocking and transforming, and such capacitors have become an indispensable component in electronic products. In the related art, the wound capacitor can only be placed upright on the circuit substrate without bending the conductive pins, so that the vertical wound capacitors cannot be used in highly space-constrained environments.

### SUMMARY OF THE DISCLOSURE

In response to the above-referenced technical inadequacy, the present disclosure provides a laterally placed capacitor package assembly and an assembly method thereof.

In order to solve the above-mentioned problems, one of the technical aspects adopted by the present disclosure is to provide a laterally placed capacitor package assembly configured to be laterally disposed on a circuit substrate, which includes a wound capacitor package structure and a capacitor supporting structure. The wound capacitor package structure includes a wound assembly, a conductive assembly and a package assembly. The wound assembly includes a wound positive conductive foil, a wound negative conductive foil and two wound separators, the conductive assembly includes a first conductive pin electrically contacting the wound positive conductive foil and a second conductive pin electrically contacting the wound negative conductive foil, and the wound assembly is disposed inside the package assembly. The capacitor supporting structure includes a supporting portion configured to support the wound capacitor package structure and a plurality of positioning portions extending outward from the supporting portion. One of the two wound separators is disposed between the wound positive conductive foil and the wound negative conductive foil, and one of the wound positive conductive foil and the wound negative conductive foil is disposed between the two wound separators. The first conductive pin includes a first embedded portion accommodated inside the package assembly and a first exposed portion exposed outside the package assembly, and the second conductive pin includes a second embedded portion accommodated inside the package assembly and a second exposed portion exposed outside the package assembly. When the capacitor supporting structure is configured to be disposed on the circuit substrate, the supporting portion of the capacitor supporting structure is configured to pass through the circuit substrate, and the plurality of positioning portions of the capacitor supporting structure are configured to be disposed on the circuit substrate for limiting a position of the capacitor supporting structure relative to the circuit substrate. When the wound capacitor package structure is configured to be laterally disposed on the capacitor supporting structure, the first exposed portion of the first conductive pin and the second exposed portion of the second conductive pin laterally extend from the package assembly without bending and are electrically connected to the circuit substrate.

In order to solve the above-mentioned problems, another one of the technical aspects adopted by the present disclosure is to provide a laterally placed capacitor package assembly, which includes a wound capacitor package structure and a capacitor supporting structure. The wound capacitor package structure includes a wound assembly, a conductive assembly and a package assembly. The conductive assembly includes a first conductive pin electrically contacting the wound assembly and a second conductive pin electrically contacting the wound assembly, and the wound assembly is disposed inside the package assembly. The capacitor supporting structure includes a supporting portion configured to support the wound capacitor package structure and a plurality of positioning portions extending outward from the supporting portion. The first conductive pin includes a first embedded portion accommodated inside the package assembly and a first exposed portion exposed outside the package assembly, and the second conductive pin includes a second embedded portion accommodated inside the package assembly and a second exposed portion exposed outside the package assembly. The first exposed portion of the first conductive pin and the second exposed portion of the second conductive pin laterally extend from the package assembly without bending.

In order to solve the above-mentioned problems, yet another one of the technical aspects adopted by the present disclosure is to provide an assembly method of a laterally placed capacitor package assembly, which includes: providing a wound capacitor package structure and a capacitor supporting structure on a circuit substrate, in which the capacitor supporting structure has a supporting portion passing through the circuit substrate and a plurality of positioning portions disposed on the circuit substrate; and then electrically connecting the wound capacitor package structure to the circuit substrate. The wound capacitor package structure includes a wound assembly, a conductive assembly and a package assembly, the conductive assembly includes a first conductive pin electrically contacting the wound assembly and a second conductive pin electrically contacting the wound assembly, and the wound assembly is disposed inside the package assembly. The supporting portion of the capacitor supporting structure is configured to support the wound capacitor package structure, and the plurality of positioning portions of the capacitor supporting structure are configured to extend outward from the supporting portion. The first exposed portion of the first conductive pin and the second exposed portion of the second conductive pin laterally extend from the package assembly without bending and are electrically connected to the circuit substrate.

In one of the possible or preferred embodiments, the step of providing the wound capacitor package structure and the capacitor supporting structure on the circuit substrate further includes: laterally placing the wound capacitor package structure on the capacitor supporting structure; and then placing the capacitor supporting structure that is configured to support the wound capacitor package structure on the circuit substrate.

In one of the possible or preferred embodiments, the step of providing the wound capacitor package structure and the capacitor supporting structure on the circuit substrate further includes: placing the capacitor supporting structure on the circuit substrate; and then laterally placing the wound capacitor package structure on the capacitor supporting structure.

In one of the possible or preferred embodiments, the package assembly includes a package casing configured to accommodate the wound assembly and a bottom sealing structure disposed inside the package casing to cooperate with the package casing, and the package assembly is completely enclosed by the package casing and the bottom sealing structure.

In one of the possible or preferred embodiments, the supporting portion of the capacitor supporting structure has an accommodating space, and a portion of the package assembly of the wound capacitor package structure is accommodated in the accommodating space of the supporting portion.

In one of the possible or preferred embodiments, the supporting portion of the capacitor supporting structure has a plurality of heat dissipation openings for partially exposing an outer surface of the package casing of the package assembly of the wound capacitor package structure.

In one of the possible or preferred embodiments, when the capacitor supporting structure is configured to be disposed on the circuit substrate, the plurality of positioning portions of the capacitor supporting structure are configured to be disposed on an upper surface or a lower surface of the circuit substrate.

In one of the possible or preferred embodiments, when the capacitor supporting structure is configured to be disposed on the circuit substrate, the plurality of positioning portions of the capacitor supporting structure are configured to be respectively fixed on a plurality of positioning areas of the circuit substrate, and each of the plurality of positioning areas is a recessed area or a planar area.

In one of the possible or preferred embodiments, when the capacitor supporting structure is configured to be disposed on the circuit substrate, the supporting portion of the capacitor supporting structure is configured to pass through a strip-shaped opening of the circuit substrate, and the plurality of positioning portions of the capacitor supporting structure are arranged along two long sides or two short sides of the strip-shaped opening of the circuit substrate, and the plurality of positioning portions of the capacitor supporting structure are separate from each other and correspond to each other, or connected with each other to form a single positioning portion.

In one of the possible or preferred embodiments, when the wound capacitor package structure is configured to be laterally disposed on the capacitor supporting structure, a first flat area of the first exposed portion of the first conductive pin and a second flat area of the second exposed portion of the second conductive pin respectively and electrically contact a first soldering area and a second soldering area of the circuit substrate.

Therefore, in the laterally placed capacitor package assembly provided by the present disclosure, by virtue of “the capacitor supporting structure including a supporting portion configured to support the wound capacitor package structure and a plurality of positioning portions extending outward from the supporting portion” and “the first exposed portion of the first conductive pin and the second exposed portion of the second conductive pin laterally extending from the package assembly without bending,” when the laterally placed capacitor package assembly is configured to be laterally disposed on a circuit substrate, the first exposed portion of the first conductive pin and the second exposed portion of the second conductive pin can be laterally and electrically connected to the circuit substrate without bending.

Furthermore, in the assembly method of the laterally placed capacitor package assembly provided by the present disclosure, by virtue of “providing a wound capacitor package structure and a capacitor supporting structure on a circuit substrate, in which the capacitor supporting structure has a supporting portion passing through the circuit substrate and a plurality of positioning portions disposed on the circuit substrate” and “electrically connecting the wound capacitor package structure to the circuit substrate,” when the laterally placed capacitor package assembly is configured to be laterally disposed on a circuit substrate, the first exposed portion of the first conductive pin and the second exposed portion of the second conductive pin can be laterally and electrically connected to the circuit substrate without bending.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of the cooperation of a wound assembly and a conductive assembly provided by the present disclosure (before a first exposed portion of a first conductive pin and a second exposed portion of a second conductive pin are flattened);

FIG. 2 is a schematic perspective exploded view of a laterally placed capacitor package assembly provided by the present disclosure;

FIG. 3 is a schematic perspective assembled view of the laterally placed capacitor package assembly provided by the present disclosure;

FIG. 4 is a schematic top view of the laterally placed capacitor package assembly provided by the present disclosure;

FIG. 5 is a schematic cross-sectional view taken along line V-V of FIG. 4;

FIG. 6 is a schematic cross-sectional view taken along line VI-VI of FIG. 4;

FIG. 7 is a schematic perspective view of the laterally placed capacitor package assembly provided by the present disclosure using another capacitor supporting structure;

FIG. 8 is a flowchart of an assembly method of the laterally placed capacitor package assembly provided by the present disclosure;

FIG. 9 is a schematic view of step S1002 of the assembly method of the laterally placed capacitor package assembly provided by the present disclosure; and

FIG. 10 is a schematic view of step S1006 of the assembly method of the laterally placed capacitor package assembly provided by the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

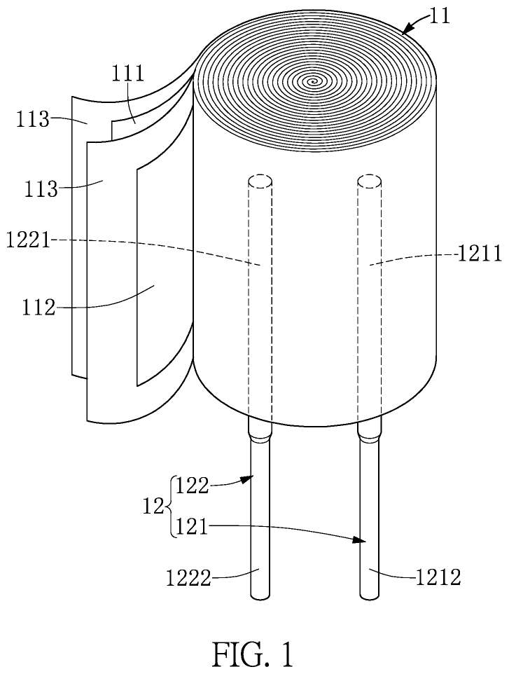

Referring to FIG. 1 to FIG. 6, a first embodiment of the present disclosure provides a laterally placed capacitor package assembly S (such as a horizontally placed capacitor package assembly) configured to be laterally (such as horizontally) disposed on a circuit substrate P, which includes a wound capacitor package structure 1 and a capacitor supporting structure 2 (such as a capacitor carrying structure or a capacitor holding structure).

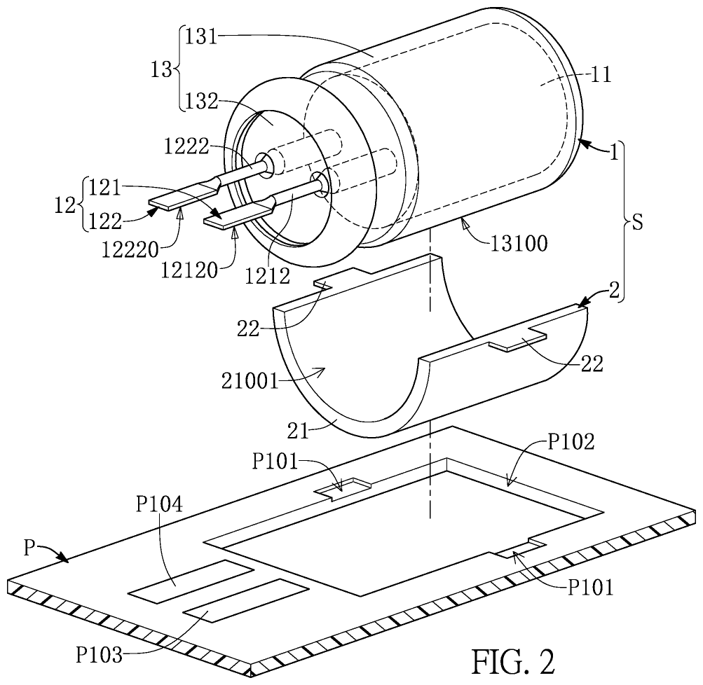

Firstly, referring to FIG. 1 and FIG. 2, the wound capacitor package structure 1 includes a wound assembly 11, a conductive assembly 12 and a package assembly 13. More particularly, the wound assembly 11 includes a wound positive conductive foil 111, a wound negative conductive foil 112 and two wound separators 113 (such as two insulating pieces), the conductive assembly 12 includes a first conductive pin 121 electrically contacting the wound positive conductive foil 111 and a second conductive pin 122 electrically contacting the wound negative conductive foil 112 (FIG. 1 shows that the first conductive pin 121 and the second conductive pin 122 have not been flattened), and the wound assembly 11 is disposed inside or enclosed by the package assembly 13.

For example, referring to FIG. 1 and FIG. 2, the wound positive conductive foil 111 and the wound negative conductive foil 112 can be conductive foils made of any conductive material, and the wound separator 113 can be an insulating paper or insulating foil containing a dipping or impregnated material such as a conductive polymer. Furthermore, one of the two wound separators 113 can be disposed between the wound positive conductive foil 111 and the wound negative conductive foil 112, and one of the wound positive conductive foil 111 and the wound negative conductive foil 112 can be disposed between the two wound separators 113 (for example, FIG. 1 shows that the wound positive conductive foil 111 is disposed between the two wound separators 113). Moreover, the first conductive pin 121 includes a first embedded portion 1211 accommodated inside the package assembly 13 and a first exposed portion 1212 exposed outside the package assembly 13 (for example, FIG. 2 shows that a part of the first exposed portion 1212 has been flattened), and the second conductive pin 122 includes a second embedded portion 1221 accommodated inside the package assembly 13 and a second exposed portion 1222 exposed outside the package assembly 13 (for example, FIG. 2 shows that a part of the second exposed portion 1222 has been flattened). In addition, the package assembly 13 includes a package casing 131 (such as an aluminum casing or a casing made of any type of material) configured to accommodate the wound assembly 11 and a bottom sealing structure 132 disposed inside the package casing 131 (such as an insulating rubber body, an insulating silicone body or an insulating epoxy body that can be surroundingly pressed by the package casing 131) to cooperate with the package casing 131, and the package assembly 13 can be completely enclosed by the package casing 131 and the bottom sealing structure 132. However, the aforementioned details are disclosed for exemplary purposes only, and are not meant to limit the scope of the present disclosure.

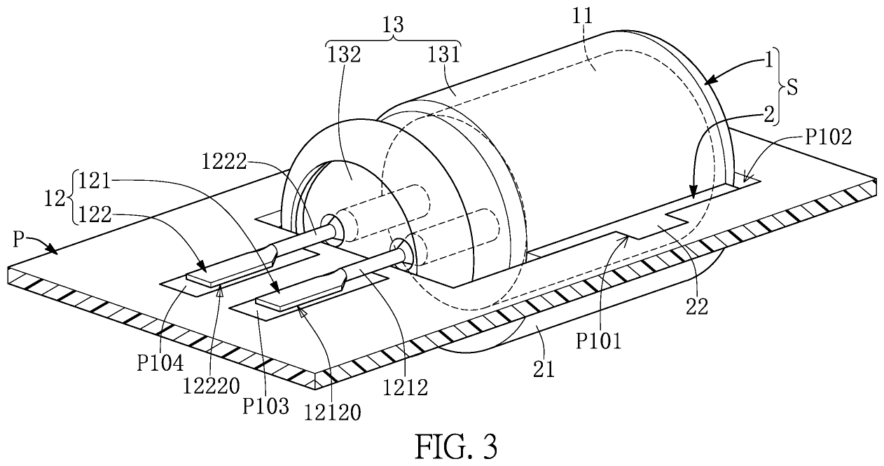

Moreover, referring to FIG. 2 and FIG. 3, the capacitor supporting structure 2 includes a supporting portion 21 (such as a carrying portion or a holding portion) configured to support or carry the wound capacitor package structure 1 and a plurality of positioning portions 22 extending outward from the supporting portion 21. For example, the supporting portion 21 of the capacitor supporting structure 2 has an accommodating space 21001 that can be formed as a semi-arc shape or any shape that can conform to the shape of the package casing 131, and a portion of the package assembly 13 of the wound capacitor package structure 1 can be accommodated in the accommodating space 21001 of the supporting portion 21. In addition, the package casing 131 of the package assembly 13 of the wound capacitor package structure 1 has an outer surface 13100, and most of the outer surface 13100 of the package casing 131 is exposed outside the capacitor supporting structure 2 which will facilitate heat dissipation of the wound capacitor package structure 1. It should be noted that the wound capacitor package structure 1 can be carried and supported by a predetermined strength through the capacitor supporting structure 2, so that the wound capacitor package structure 1 can be configured to effectively resist vibration. In other words, the first conductive pin 121 and the second exposed portion 1222 of the wound capacitor package structure 1 are not easily separated from the electrical connection relationship with the circuit substrate P due to external vibrations. However, the aforementioned details are disclosed for exemplary purposes only, and are not meant to limit the scope of the present disclosure.

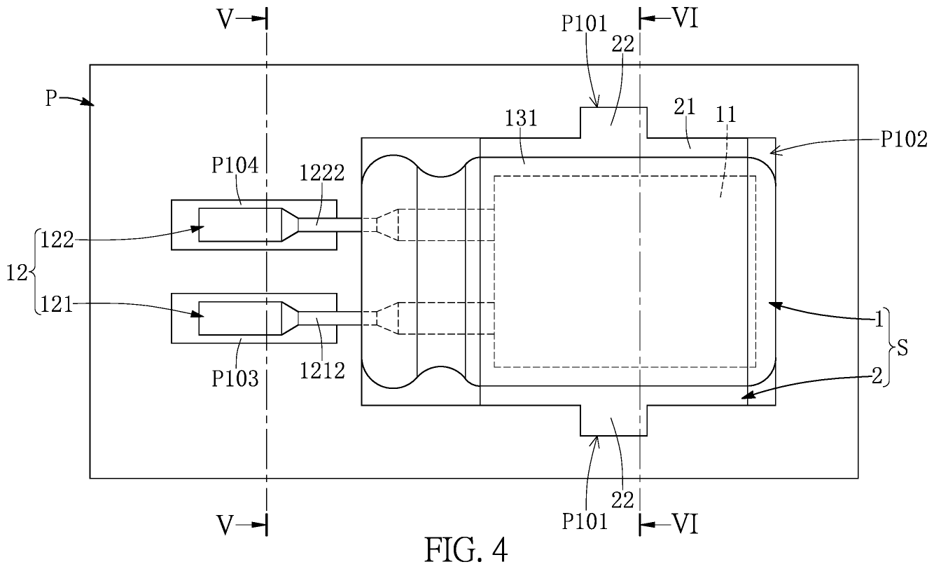

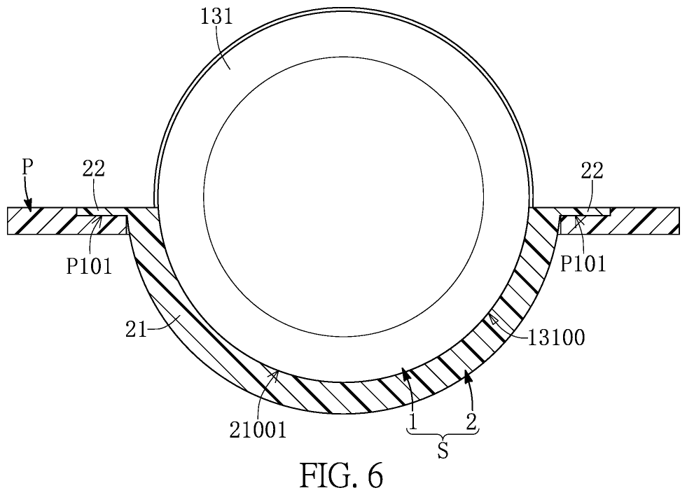

More particularly, for example, referring to FIG. 3, FIG. 4 and FIG. 6, when the capacitor supporting structure 2 is configured to be disposed on the circuit substrate P, the supporting portion 21 of the capacitor supporting structure 2 can be configured to pass through the circuit substrate P, and the plurality of positioning portions 22 of the capacitor supporting structure 2 can be configured to be disposed on the circuit substrate P for limiting or restrict a position of the capacitor supporting structure 2 relative to the circuit substrate P. However, the aforementioned details are disclosed for exemplary purposes only, and are not meant to limit the scope of the present disclosure.

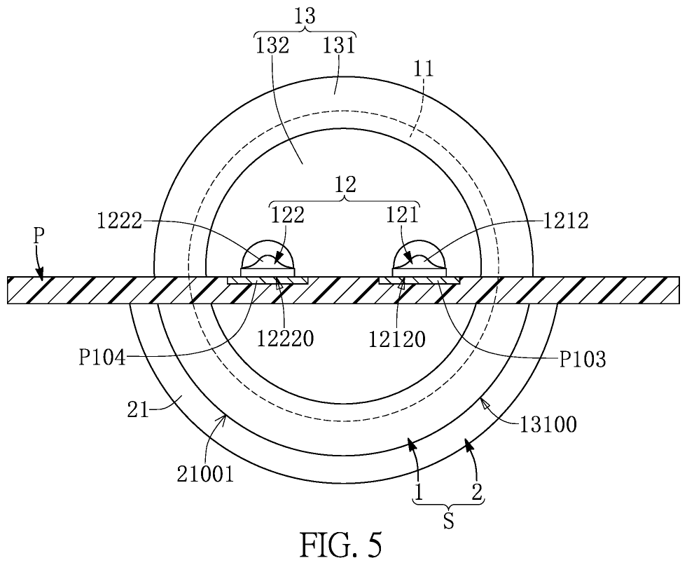

More particularly, for example, referring to FIG. 3, FIG. 4 and FIG. 5, when the wound capacitor package structure 1 is configured to be laterally or horizontally disposed on the capacitor supporting structure 2, the first exposed portion 1212 of the first conductive pin 121 and the second exposed portion 1222 of the second conductive pin 122 can laterally or horizontally extend from the package assembly 13 without bending (i.e., do not bend the first exposed portion 1212 and the second exposed portion 1222) and be electrically connected to the circuit substrate P. It should be noted that the first exposed portion 1212 of the first conductive pin 121 and the second exposed portion 1222 of the second conductive pin 122 are electrically connected to the circuit substrate P without bending, the wound capacitor package structure 1 can provide electrical characteristics that meet market demand (or customer demand). However, the aforementioned details are disclosed for exemplary purposes only, and are not meant to limit the scope of the present disclosure.

More particularly, for example, referring to FIG. 3, FIG. 4 and FIG. 6, when the capacitor supporting structure 2 is configured to be disposed on the circuit substrate P, the plurality of positioning portions 22 of the capacitor supporting structure 2 can be configured to be disposed on an upper surface or a lower surface of the circuit substrate P. That is to say, the user can selectively or optionally place the laterally placed capacitor package assembly S laterally on the upper surface or the lower surface of the circuit substrate P according to different requirements. However, the aforementioned details are disclosed for exemplary purposes only, and are not meant to limit the scope of the present disclosure.

More particularly, for example, referring to FIG. 2, FIG. 3 and FIG. 6, when the capacitor supporting structure 2 is configured to be disposed on the circuit substrate P, the plurality of positioning portions 22 of the capacitor supporting structure 2 can be configured to be respectively fixed or positioned on a plurality of positioning areas P101 of the circuit substrate P, and each of the plurality of positioning areas P101 can be a recessed area (as shown in FIG. 2, the present disclosure takes as an example that each of the positioning areas P101 can be a recessed area) or a planar area (such as an area flush with the upper surface of the circuit board P). For example, when the plurality of positioning portions 22 of the capacitor supporting structure 2 are configured to be respectively fixed in the plurality of recessed areas (i.e., the plurality of positioning areas P101) of the circuit substrate P, the position of the capacitor supporting structure 2 relative to the circuit substrate P can be limited through cooperation of the positioning portions 22 and the recessed area (i.e., the plurality of positioning areas P101). However, the aforementioned details are disclosed for exemplary purposes only, and are not meant to limit the scope of the present disclosure.

More particularly, for example, referring to FIG. 2, FIG. 3 and FIG. 4, when the capacitor supporting structure 2 is configured to be disposed on the circuit substrate P, the supporting portion 21 of the capacitor supporting structure 2 can be configured to pass through a strip-shaped opening P102 (or an elongated opening) of the circuit substrate P. It should be noted that the plurality of positioning portions 22 of the capacitor supporting structure 2 can be arranged along two long sides or two short sides of the strip-shaped opening P102 of the circuit substrate P (as shown in FIG. 2, the present disclosure takes as an example that the positioning portions 22 are arranged along the two long sides of the strip-shaped opening P102 of the circuit substrate P), and the plurality of positioning portions 22 of the capacitor supporting structure 2 can be separated from each other and correspond to each other, or can be connected with each other to form a single positioning portion (FIG. 2 illustrates an example in which the plurality of positioning portions 22 are separate from each other and correspond to each other). However, the aforementioned details are disclosed for exemplary purposes only, and are not meant to limit the scope of the present disclosure.

More particularly, for example, referring to FIG. 2, FIG. 3 and FIG. 5, when the wound capacitor package structure 1 is configured to be laterally or horizontally disposed on the capacitor supporting structure 2, a first flat area 12120 of the first exposed portion 1212 of the first conductive pin 121 and a second flat area 12220 of the second exposed portion 1222 of the second conductive pin 122 can respectively and electrically contact a first soldering area P103 and a second soldering area P104 of the circuit substrate P by soldering. It should be noted that the first flat area 12120 and the second flat area 12220 shown in FIG. 2 are areas formed by flattening the first exposed portion 1212 and the second exposed portion 1222 shown in FIG. 1 to increase a soldering area between the first exposed portion 1212 of the first conductive pin 121 and the first soldering area P103 of the circuit substrate P, and between the second exposed portion 1222 of the second conductive pin 122 and the second soldering area P104 of the circuit substrate P. However, the aforementioned details are disclosed for exemplary purposes only, and are not meant to limit the scope of the present disclosure.

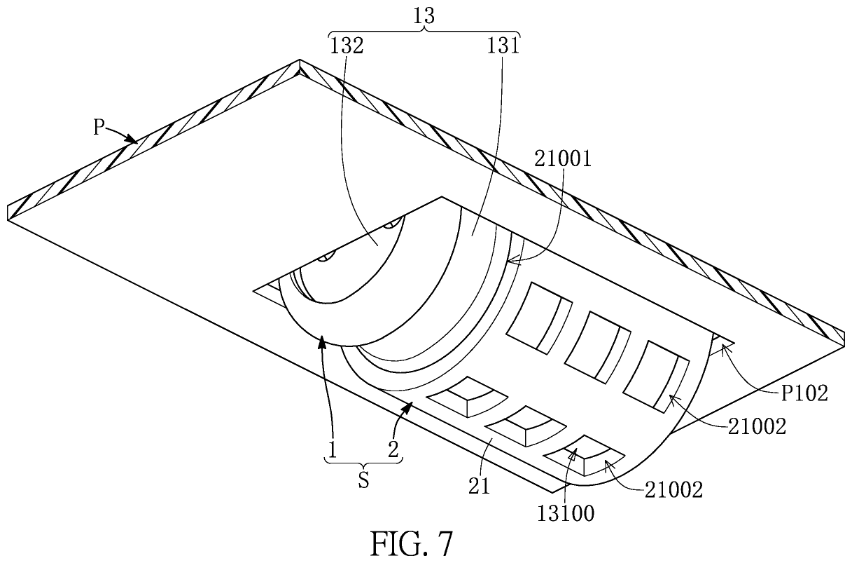

It should be noted that as shown in FIG. 7, in another possible embodiment, the supporting portion 21 of the capacitor supporting structure 2 has a plurality of heat dissipation openings 21002 for partially exposing an outer surface 13100 of the package casing 131 of the package assembly 13 of the wound capacitor package structure 1. Therefore, the wound capacitor package structure 1 can not only dissipate heat through the exposed area that is not shielded by the supporting portion 21 of the capacitor carrying structure 2, but the wound capacitor package structure 1 can also dissipate heat through the heat dissipation openings 21002 of the supporting portion 21. However, the aforementioned details are disclosed for exemplary purposes only, and are not meant to limit the scope of the present disclosure.

### Second Embodiment

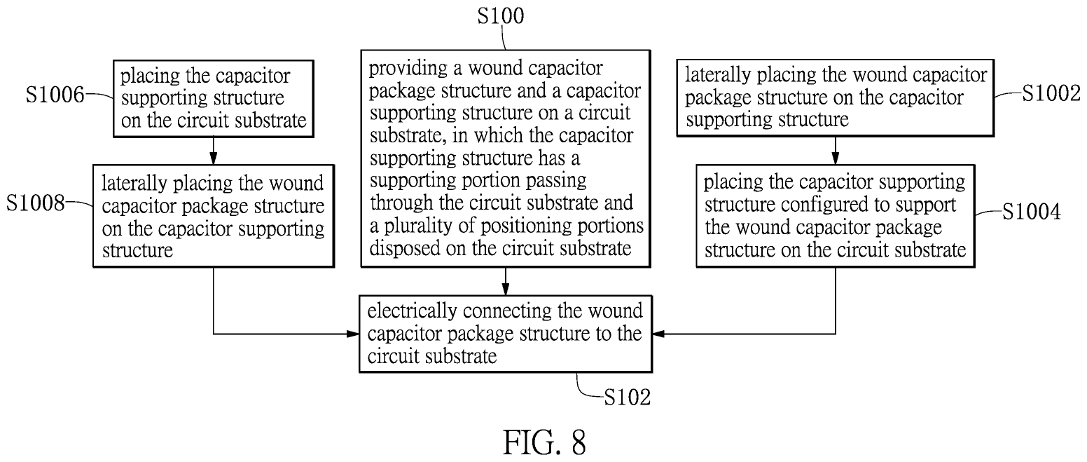

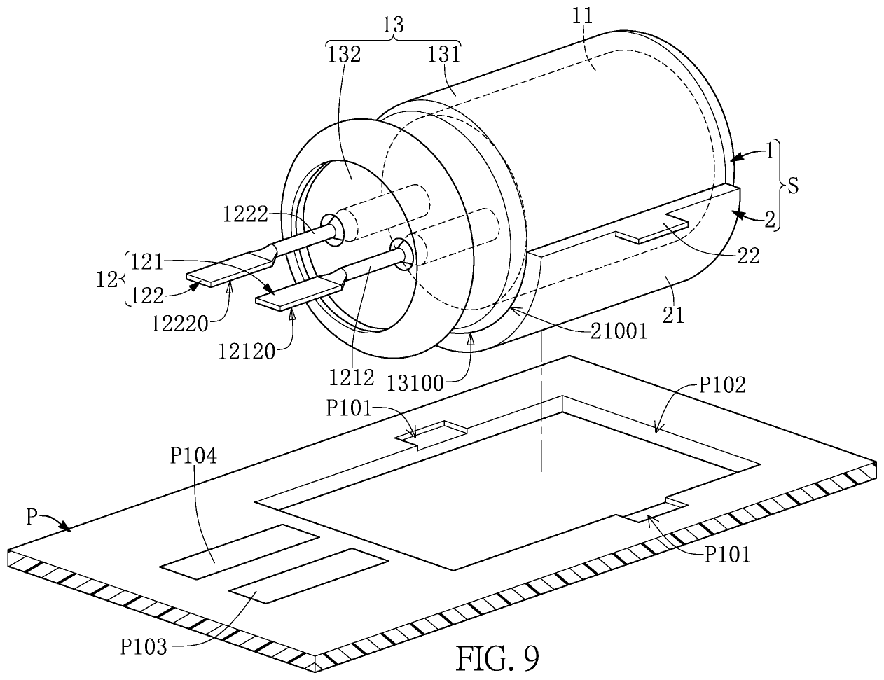

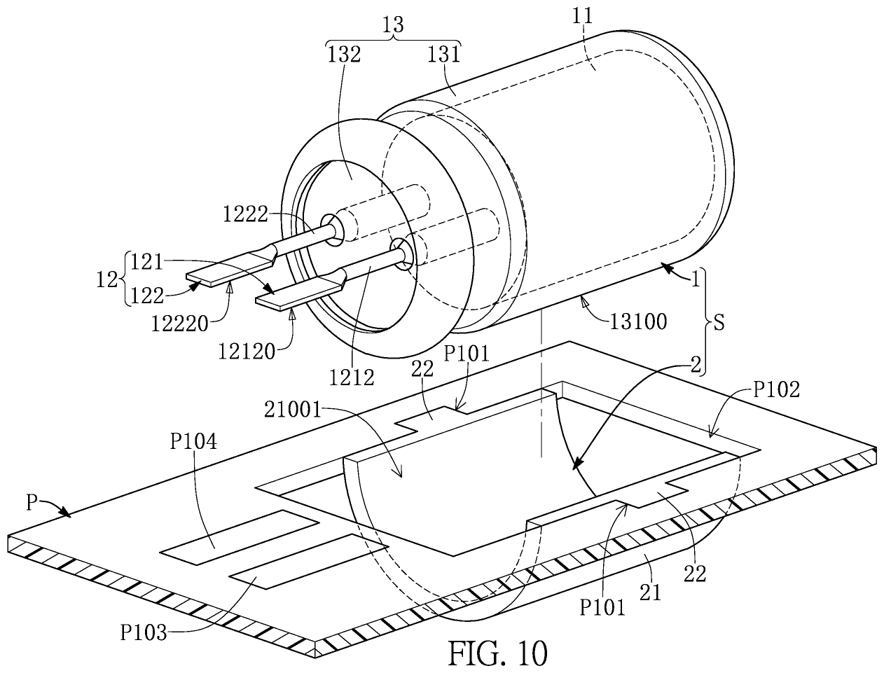

Referring to FIG. 3, FIG. 8, FIG. 9 and FIG. 10, a second embodiment of the present disclosure provides an assembly method of a laterally placed capacitor package assembly S, which includes: firstly, providing a wound capacitor package structure 1 and a capacitor supporting structure 2 on a circuit substrate P, in which the capacitor supporting structure 2 has a supporting portion 21 passing through the circuit substrate P and a plurality of positioning portions 22 disposed on the circuit substrate P (step S100); and then electrically connecting the wound capacitor package structure 1 to the circuit substrate P by soldering or any conductive method (step S102). More particularly, the wound capacitor package structure 1 includes a wound assembly 11, a conductive assembly 12 and a package assembly 13, the conductive assembly 12 includes a first conductive pin 121 electrically contacting the wound assembly 11 and a second conductive pin 122 electrically contacting the wound assembly 11, and the wound assembly 11 is disposed inside (or can be enclosed by) the package assembly 13. Moreover, the supporting portion 21 of the capacitor supporting structure 2 is configured to support or carry the wound capacitor package structure 1, and the plurality of positioning portions 22 of the capacitor supporting structure 2 are configured to extend outward from the supporting portion 21. In addition, the first exposed portion 1212 of the first conductive pin 121 and the second exposed portion 1222 of the second conductive pin 122 laterally or horizontally extend from the package assembly 13 without bending and are electrically connected to the circuit substrate P.

For example, referring to FIG. 3, FIG. 8 and FIG. 9, the step S100 of providing the wound capacitor package structure 1 and the capacitor supporting structure 2 on the circuit substrate P further includes: firstly, referring to FIG. 8 and FIG. 9, laterally or horizontally placing the wound capacitor package structure 1 on the capacitor supporting structure 2 (step S1002); and then referring to FIG. 3 and FIG. 8, placing the capacitor supporting structure 2 that is configured to support the wound capacitor package structure 1 on the circuit substrate P (step S1004). However, the aforementioned details are disclosed for exemplary purposes only, and are not meant to limit the scope of the present disclosure.

For example, referring to FIG. 3, FIG. 8 and FIG. 10, the step S100 of providing the wound capacitor package structure 1 and the capacitor supporting structure 2 on the circuit substrate P further includes: firstly, referring to FIG. 8 and FIG. 10, placing the capacitor supporting structure 2 on the circuit substrate P (step S1006); and then referring to FIG. 3 and FIG. 8, laterally or horizontally placing the wound capacitor package structure 1 on the capacitor supporting structure 2 (step S1008). However, the aforementioned details are disclosed for exemplary purposes only, and are not meant to limit the scope of the present disclosure.

### Beneficial Effects of the Embodiments

In conclusion, in the laterally placed capacitor package assembly S provided by the present disclosure, by virtue of “the capacitor supporting structure 2 including a supporting portion 21 configured to support the wound capacitor package structure 1 and a plurality of positioning portions 22 extending outward from the supporting portion 21” and “the first exposed portion 1212 of the first conductive pin 121 and the second exposed portion 1222 of the second conductive pin 122 laterally extending from the package assembly 13 without bending,” when the laterally placed capacitor package assembly S is configured to be laterally disposed on a circuit substrate P, the first exposed portion 1212 of the first conductive pin 121 and the second exposed portion 1222 of the second conductive pin 122 can be laterally and electrically connected to the circuit substrate P without bending.

Furthermore, in the assembly method of the laterally placed capacitor package assembly S provided by the present disclosure, by virtue of “providing a wound capacitor package structure 1 and a capacitor supporting structure 2 on a circuit substrate P, in which the capacitor supporting structure 2 has a supporting portion 21 passing through the circuit substrate P and a plurality of positioning portions 22 disposed on the circuit substrate P” and “electrically connecting the wound capacitor package structure 1 to the circuit substrate P,” when the laterally placed capacitor package assembly S is configured to be laterally disposed on a circuit substrate P, the first exposed portion 1212 of the first conductive pin 121 and the second exposed portion 1222 of the second conductive pin 122 can be laterally and electrically connected to the circuit substrate P without bending.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A laterally placed capacitor package assembly configured to be laterally disposed on a circuit substrate, comprising:
a wound capacitor package structure including a wound assembly, a conductive assembly and a package assembly, wherein the wound assembly includes a wound positive conductive foil, a wound negative conductive foil and two wound separators, the conductive assembly includes a first conductive pin electrically contacting the wound positive conductive foil and a second conductive pin electrically contacting the wound negative conductive foil, and the wound assembly is disposed inside the package assembly; and
a capacitor supporting structure including a supporting portion configured to support the wound capacitor package structure and a plurality of positioning portions extending outward from the supporting portion;
wherein, one of the two wound separators is disposed between the wound positive conductive foil and the wound negative conductive foil, and one of the wound positive conductive foil and the wound negative conductive foil is disposed between the two wound separators;
wherein the first conductive pin includes a first embedded portion accommodated inside the package assembly and a first exposed portion exposed outside the package assembly, and the second conductive pin includes a second embedded portion accommodated inside the package assembly and a second exposed portion exposed outside the package assembly;
wherein, when the capacitor supporting structure is configured to be disposed on the circuit substrate, the supporting portion of the capacitor supporting structure is configured to pass through the circuit substrate, and the plurality of positioning portions of the capacitor supporting structure are configured to be disposed on the circuit substrate for limiting a position of the capacitor supporting structure relative to the circuit substrate;
wherein, when the wound capacitor package structure is configured to be laterally disposed on the capacitor supporting structure, the first exposed portion of the first conductive pin and the second exposed portion of the second conductive pin laterally extend from the package assembly without bending and are electrically connected to the circuit substrate.

2. The laterally placed capacitor package assembly according to claim 1,
wherein the package assembly includes a package casing configured to accommodate the wound assembly and a bottom sealing structure disposed inside the package casing to cooperate with the package casing, and the package assembly is completely enclosed by the package casing and the bottom sealing structure;
wherein the supporting portion of the capacitor supporting structure has an accommodating space, and a portion of the package assembly of the wound capacitor package structure is accommodated in the accommodating space of the supporting portion;
wherein the supporting portion of the capacitor supporting structure has a plurality of heat dissipation openings for partially exposing an outer surface of the package casing of the package assembly of the wound capacitor package structure.

3. The laterally placed capacitor package assembly according to claim 1,
wherein, when the capacitor supporting structure is configured to be disposed on the circuit substrate, the plurality of positioning portions of the capacitor supporting structure are configured to be disposed on an upper surface or a lower surface of the circuit substrate;
wherein, when the capacitor supporting structure is configured to be disposed on the circuit substrate, the plurality of positioning portions of the capacitor supporting structure are configured to be respectively fixed on a plurality of positioning areas of the circuit substrate, and each of the plurality of positioning areas is a recessed area or a planar area;
wherein, when the capacitor supporting structure is configured to be disposed on the circuit substrate, the supporting portion of the capacitor supporting structure is configured to pass through a strip-shaped opening of the circuit substrate, and the plurality of positioning portions of the capacitor supporting structure are arranged along two long sides or two short sides of the strip-shaped opening of the circuit substrate, and the plurality of positioning portions of the capacitor supporting structure are separate from each other and correspond to each other, or connected with each other to form a single positioning portion;
wherein, when the wound capacitor package structure is configured to be laterally disposed on the capacitor supporting structure, a first flat area of the first exposed portion of the first conductive pin and a second flat area of the second exposed portion of the second conductive pin respectively and electrically contact a first soldering area and a second soldering area of the circuit substrate.

4. A laterally placed capacitor package assembly, comprising:
a wound capacitor package structure including a wound assembly, a conductive assembly and a package assembly, wherein the conductive assembly includes a first conductive pin electrically contacting the wound assembly and a second conductive pin electrically contacting the wound assembly, and the wound assembly is disposed inside the package assembly; and
a capacitor supporting structure including a supporting portion configured to support the wound capacitor package structure and a plurality of positioning portions extending outward from the supporting portion;
wherein the first conductive pin includes a first embedded portion accommodated inside the package assembly and a first exposed portion exposed outside the package assembly, and the second conductive pin includes a second embedded portion accommodated inside the package assembly and a second exposed portion exposed outside the package assembly;
wherein the first exposed portion of the first conductive pin and the second exposed portion of the second conductive pin laterally extend from the package assembly without bending.

5. The laterally placed capacitor package assembly according to claim 4,
wherein the package assembly includes a package casing configured to accommodate the wound assembly and a bottom sealing structure disposed inside the package casing to cooperate with the package casing, and the package assembly is completely enclosed by the package casing and the bottom sealing structure;
wherein the supporting portion of the capacitor supporting structure has an accommodating space, and a portion of the package assembly of the wound capacitor package structure is accommodated in the accommodating space of the supporting portion;
wherein the supporting portion of the capacitor supporting structure has a plurality of heat dissipation openings for partially exposing an outer surface of the package casing of the package assembly of the wound capacitor package structure.

6. The laterally placed capacitor package assembly according to claim 4,
wherein the laterally placed capacitor package assembly is configured to be laterally disposed on a circuit substrate;
wherein, when the capacitor supporting structure is configured to be disposed on the circuit substrate, the plurality of positioning portions of the capacitor supporting structure are configured to be disposed on an upper surface or a lower surface of the circuit substrate;
wherein, when the capacitor supporting structure is configured to be disposed on the circuit substrate, the plurality of positioning portions of the capacitor supporting structure are configured to be respectively fixed on a plurality of positioning areas of the circuit substrate, and each of the plurality of positioning areas is a recessed area or a planar area;
wherein, when the capacitor supporting structure is configured to be disposed on the circuit substrate, the supporting portion of the capacitor supporting structure is configured to pass through a strip-shaped opening of the circuit substrate, and the plurality of positioning portions of the capacitor supporting structure are arranged along two long sides or two short sides of the strip-shaped opening of the circuit substrate, and the plurality of positioning portions of the capacitor supporting structure are separate from each other and correspond to each other, or connected with each other to form a single positioning portion;
wherein, when the wound capacitor package structure is configured to be laterally disposed on the capacitor supporting structure, a first flat area of the first exposed portion of the first conductive pin and a second flat area of the second exposed portion of the second conductive pin respectively and electrically contact a first soldering area and a second soldering area of the circuit substrate.

7. An assembly method of a laterally placed capacitor package assembly, comprising:
providing a wound capacitor package structure and a capacitor supporting structure on a circuit substrate, wherein the capacitor supporting structure has a supporting portion passing through the circuit substrate and a plurality of positioning portions disposed on the circuit substrate; and
electrically connecting the wound capacitor package structure to the circuit substrate;
wherein the wound capacitor package structure includes a wound assembly, a conductive assembly and a package assembly, the conductive assembly includes a first conductive pin electrically contacting the wound assembly and a second conductive pin electrically contacting the wound assembly, and the wound assembly is disposed inside the package assembly;
wherein the supporting portion of the capacitor supporting structure is configured to support the wound capacitor package structure, and the plurality of positioning portions of the capacitor supporting structure are configured to extend outward from the supporting portion;
wherein the first exposed portion of the first conductive pin and the second exposed portion of the second conductive pin laterally extend from the package assembly without bending and are electrically connected to the circuit substrate.

8. The assembly method according to claim 7, wherein the step of providing the wound capacitor package structure and the capacitor supporting structure on the circuit substrate further includes:
laterally placing the wound capacitor package structure on the capacitor supporting structure; and
placing the capacitor supporting structure that is configured to support the wound capacitor package structure on the circuit substrate.

9. The assembly method according to claim 7, wherein the step of providing the wound capacitor package structure and the capacitor supporting structure on the circuit substrate further includes:
placing the capacitor supporting structure on the circuit substrate; and
laterally placing the wound capacitor package structure on the capacitor supporting structure.

10. The assembly method according to claim 7,
wherein the package assembly includes a package casing configured to accommodate the wound assembly and a bottom sealing structure disposed inside the package casing to cooperate with the package casing, and the package assembly is completely enclosed by the package casing and the bottom sealing structure;
wherein the supporting portion of the capacitor supporting structure has an accommodating space, and a portion of the package assembly of the wound capacitor package structure is accommodated in the accommodating space of the supporting portion;
wherein the supporting portion of the capacitor supporting structure has a plurality of heat dissipation openings for partially exposing an outer surface of the package casing of the package assembly of the wound capacitor package structure;
wherein, when the capacitor supporting structure is configured to be disposed on the circuit substrate, the plurality of positioning portions of the capacitor supporting structure are configured to be disposed on an upper surface or a lower surface of the circuit substrate;
wherein, when the capacitor supporting structure is configured to be disposed on the circuit substrate, the plurality of positioning portions of the capacitor supporting structure are configured to be respectively fixed on a plurality of positioning areas of the circuit substrate, and each of the plurality of positioning areas is a recessed area or a planar area;
wherein, when the capacitor supporting structure is configured to be disposed on the circuit substrate, the supporting portion of the capacitor supporting structure is configured to pass through a strip-shaped opening of the circuit substrate, and the plurality of positioning portions of the capacitor supporting structure are arranged along two long sides or two short sides of the strip-shaped opening of the circuit substrate, and the plurality of positioning portions of the capacitor supporting structure are separate from each other and correspond to each other, or connected with each other to form a single positioning portion;
wherein, when the wound capacitor package structure is configured to be laterally disposed on the capacitor supporting structure, a first flat area of the first exposed portion of the first conductive pin and a second flat area of the second exposed portion of the second conductive pin respectively and electrically contact a first soldering area and a second soldering area of the circuit substrate.
